(19) United States
(12) Patent Application Publication
(10) Pub. No.: US 2013/0187662 A1
(43) Pub. Date: Jul. 25, 2013

(54) DETERMINATION OF THE LOCATION OF AN ELECTRICAL DISTURBANCE

(71) Applicant: GE Aviation Systems Limited, Gloucestershire (GB)

(72) Inventor: Andrew Ceri Davis, Gloucestershire (GB)

(73) Assignee: GE AVIATION SYSTEMS LIMITED, Gloucestershire (GB)

(21) Appl. No.: 13/745,139

(22) Filed: Jan. 18, 2013

(30) Foreign Application Priority Data
Jan. 20, 2012 (GB) 1200986.6

(51) Int. Cl. G01R 31/08

(52) U.S. Cl. CPC G01R 31/08
USPC 324/521

(57) ABSTRACT

According to an embodiment of the present invention, an apparatus for determining the location of an electrical disturbance in a circuit is provided. The apparatus has at least one sensor configured to determine the relative phase of current and voltage waveforms across the circuit inductance of a portion of the circuit produced by a voltage or current perturbation, and a controller configured to identify the location of the electrical disturbance within the circuit from the relative phase of the current and voltage waveforms.

### BACKGROUND OF THE INVENTION

Embodiments of the present invention relate to determining the location of an electrical disturbance in one or more circuits which may be caused, for example, by a fault, such as a short circuit, an open circuit, or by a lightning strike.

In many applications, a single power source is connected to a plurality of electrical loads. For example, in an aircraft a single power source may supply various loads such as cockpit instruments, air supply, environmental controls, etc. A short circuit or open circuit wiring fault may cause an electrical arc to occur resulting in further damage. All, or large parts, of the circuit may be closed down to prevent damage being caused to the various parts of the circuit as it is not generally known from which part of the circuit the electrical disturbance originates. However, it is desirable to not have to close down all, or large parts, of the circuit in the event of an electrical disturbance. This is especially true if an external electrical event, such as lightning, is mistaken for an arc fault, resulting in erroneous disconnection of fully operational circuits.

### BRIEF DESCRIPTION OF THE INVENTION

According to an embodiment of the present invention, an apparatus for determining the location of an electrical disturbance in a circuit is provided. The apparatus has at least one sensor configured to determine the relative phase of current and voltage waveforms across the circuit inductance of a portion of the circuit produced by a voltage or current perturbation and a controller configured to identify the location of the electrical disturbance within the circuit from the relative phase of the current and voltage waveforms.

According to another embodiment of the present invention, a circuit is provided. The circuit comprises a power source, at least one distribution leg comprising a load, and at least one apparatus for determining the location of an electrical disturbance in a circuit. The apparatus comprises at least one sensor configured to determine the relative phase of current and voltage waveforms across the circuit inductance of a portion of the circuit produced by a voltage or current perturbation, and a controller configured to identify the location of the electrical disturbance within the circuit from the relative phase of the current and voltage waveforms. The apparatus is configured to identify the location of an electrical disturbance within the power source portion or the at least one distribution leg.

According to another embodiment of the present invention a method for determining the location of an electrical disturbance in a circuit is provided. The method comprises determining the relative phase of current and voltage waveforms across the circuit inductance of a portion of the circuit produced by a voltage or current perturbation in the circuit and identifying the location of the electrical disturbance within the circuit from the determined relative phase of current and voltage waveforms in that portion of the circuit.

### BRIEF DESCRIPTION OF THE DRAWINGS

An embodiment of the present invention will now be described, by way of example only, with reference to the accompanying drawings in which:

FIG. 1 shows a schematic example of a circuit with a plurality of distribution legs and apparatus for determining the location of an electrical disturbance within the circuit in accordance with an embodiment of the present invention;

FIG. 2 shows a more detailed example of a circuit with an apparatus in accordance with an embodiment of the present invention;

FIG. 3 shows examples of waveforms produced in the circuit of FIG. 1 or FIG. 2 when the disturbance is on the load side of the circuit;

FIG. 4 shows examples of waveforms produced in the circuit of FIG. 1 or FIG. 2 when the disturbance is on the source side of the circuit; and

FIG. 5 shows a technique to reduce noise effects when determining the location of the electrical disturbance within the circuit.

### DETAILED DESCRIPTION OF THE INVENTION

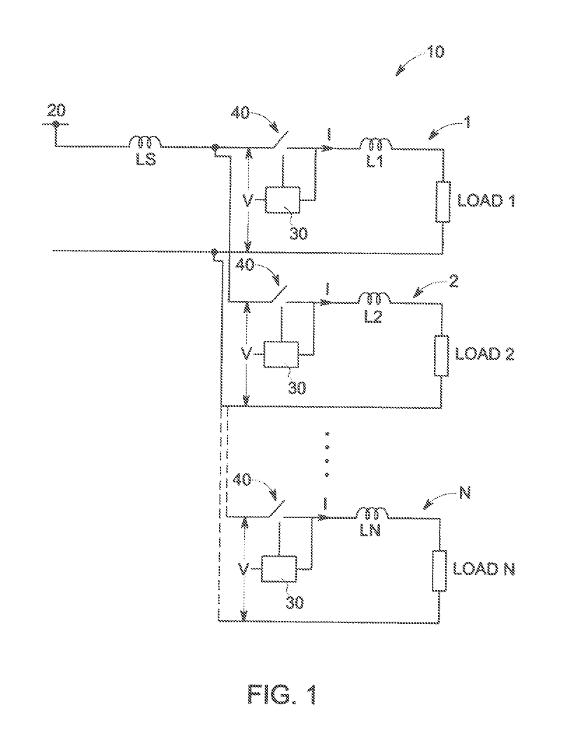

FIG. 1 shows an example of a circuit 10 having a plurality of distribution legs 1, 2 . . . N each connected to a single power source 20. Each distribution leg 1, 2 . . . N has an inherent inductance L1, L2 . . . LN. Each distribution leg 1, 2 . . . N has an electrical load to supply electrical power to a particular electrical component. In an aircraft, for example, these may include cockpit instruments, air supply, environmental controls and/or any other electrical equipment. At least one of the distribution legs includes a controller 30 for determining the relative phase of current and voltage waveforms across the circuit inductance L1, L2 . . . LN of that particular distribution leg 1,2 . . . N produced by a voltage or current perturbation, such as a fault, short circuit, open circuit or lightning strike somewhere in the overall circuit 10. From the relative phase of the current and voltage waveforms, the controller 30 is able to identify the location of the electrical disturbance within the circuit 10. For example, if the controller 30 in distribution leg 1 detects that a current waveform in that distribution leg produced by the electrical disturbance is before a corresponding voltage waveform, then the location of the electrical disturbance can be identified as being in that particular distribution leg 1. That particular distribution leg 1 may then be isolated from the remainder of the circuit 10, for example, using a switch 40. If, the current waveform in distribution leg 1 produced by an electrical disturbance is not before the corresponding voltage waveform, then the location of the electrical disturbance can be identified as being elsewhere, for example, in the power source 20 side of the circuit 10 or in another distribution leg 2 . . . N.

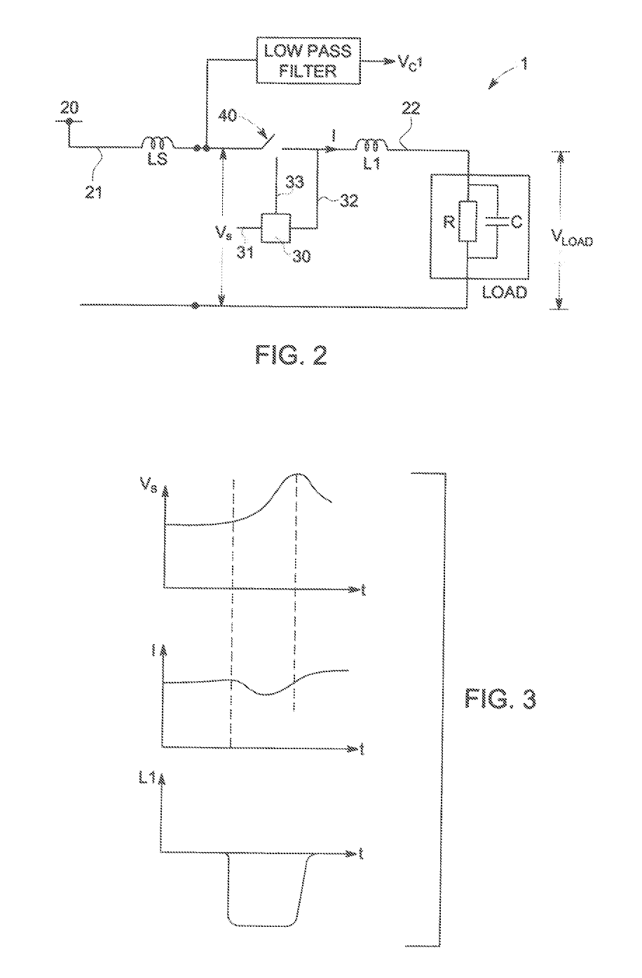

FIG. 2 shows a more detailed example of the circuit 10, but with only one distribution leg 1 illustrated. Power from the source 20 is fed to the isolation switch 40 via a cable 21 with inherent inductance LS. The power is fed out from the switch 40 to the load via a second cable 22 with inherent inductance L1. The controller 30 measures the parameters V_{S} (voltage to return) and the current I (load current) in the second cable 22. The controller 30 is arranged to measure the voltage V_{S} by any suitable means such as, for example, a suitable volt meter and to measure the current I by any suitable means such as, for example, a suitable ammeter. In this example a signal indicative of the voltage V_{S} is communicated to the controller 30 via line 31 and a signal indicative of the current I is communicated to the controller 30 via a line 32.

If a fault is introduced into the distribution leg 1 of the circuit, the power source 20 may experience periodic voltage perturbations. The fault may, for example, be a result of a short circuit, open circuit or lightning event and may produce an arc which may be in series with the load or may arc to ground across the load resulting in a parallel arc. The load may have a complex, unknown impedence that may be represented as a parallel resistance R and capacitance C as illustrated in FIG. 2.

A convenient method of determining the relative phase of the voltage and current waveforms across the inductance L1 of the distribution leg 1 during an electrical disturbance is by calculating the sign (positive or negative) of the inductance L1 of the distribution leg 1. If V_{S}, I and V_{C} (the voltage across the capacitive component C of the load) are known, for example by measurement, then the inductance L1 of the distribution leg 1 can be calculated from the formula:

$${V}_{L} = L 1 \frac{d i}{d t}$$

where V_{L}=V_{S}−V_{C}

V_{C} is not measured. As the average voltage across the inductance L1 of the distribution leg 1 is zero, V_{C} can be approximated by a low pass filtered version of V_{S} shown as V_{C}′.

When the inductance L1 of the distribution leg 1 is calculated from V_{S}, V_{C}′ and I, it has been found that perturbations occurring outside the distribution leg 1 result in a positive value for L1 while perturbations occurring within distribution leg 1 result in a negative value for L1. Determining the sign (positive or negative) of the value of L1 while the voltage and/or current are perturbed, enables the location of the electrical disturbance being either within the distribution leg 1, or externally of the distribution leg 1, to be determined. The controller 30, which may be housed within the switch 40 or separately from the switch or the entire circuit 10, for example in an external control system, microprocessor or computer, could measure V_{S} and I, and calculate V_{C}′ and L1, and thus determine the presence of a fault or arc within the distribution leg 1.

In order to reduce the likelihood of errors, for example from electrical noise within the circuit, additional filtering and/or event counting can be included to gain confidence in the detection of the presence of a fault in a particular distribution leg 1. That distribution leg may then be isolated for example by the controller 30 arranging for the opening of switch 40 via control line 33.

The inductance L1 of the distribution leg 1 and the approximated value of the voltage across the capacitive component of the load V_{C}1 can be determined using the equations provided below. The equations are presented in discrete time and the annotation n, n−1 denote the latest and previous values of a perimeter through successive calculation cycles;

A=(1−k)(V_{S}(n)−V_{C′}(n−1))

where k is a filter constant with a typical value of approximately 0.1;

$$L 1 = \frac{A}{( I ( n ) - I ( n - 1 ) )}$$

where t is the sample time interval; and

V_{C′}(n)=V_{S}(n)−A

When used in a circuit 10 with a plurality of distribution legs 1,2 . . . N as shown in FIG. 1 for example, a controller 30, for determining the presence of a fault may be provided in each distribution leg 1, 2 . . . N if desired.

FIG. 3 shows examples of voltage (V_{S}) and current (I) waveforms produced across the inductance L1 in a distribution leg 1 when a fault occurs in that distribution leg 1. As can be seen, the voltage waveform occurs after the current waveform. In particular the voltage peak occurs after the current peak. Also, as shown in FIG. 3, a detected inductance L1 in the distribution leg 1 will have a negative value at the time of the electrical disturbance.

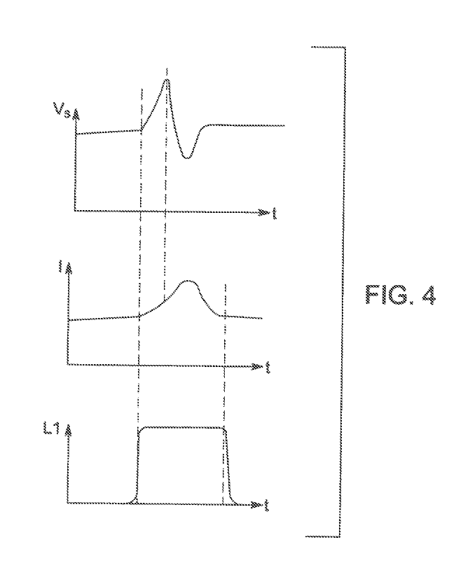

FIG. 4 shows an example of the voltage and current waveforms produced in a distribution leg resulting from an electrical disturbance external to that distribution leg, for example on the source side of the circuit or in a different distribution leg 2 . . . N. As can be seen in the waveforms of FIG. 4, in this example the voltage V_{S} waveform occurs before the current I waveform. In particular the peak voltage V_{S} occurs before the peak current I. Also, as shown in FIG. 4, the inductance L1 in the distribution leg 1 has a positive value during the electrical disturbance. Since the voltage (V_{S}) waveform occurs before the current (I) waveform and the inductance L1 in the distribution leg 1 has a positive value, it may be determined that the disturbance occurred externally to the distribution leg 1, for example on the source 20 side of the circuit 10 or in another distribution leg 2 . . . N.

An indication of the location of an electrical disturbance within a circuit, for example whether on the load side or source side of a circuit and/or within which one of a number of distribution legs may result in isolation of that part of the circuit such that the remainder of the circuit may continue in operation. An indication of the part of the circuit which suffered the electrical disturbance may also be provided to a user, such as on a display panel or graphical user interface such that a user is able to examine that part of the circuit which experienced the electrical disturbance.

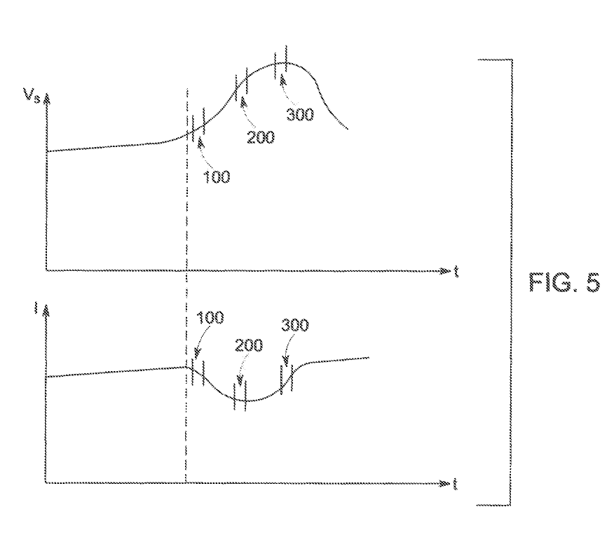

FIG. 5 shows a technique to reduce noise effects when determining the location of an electrical disturbance within the circuit 10. In this example samples of the voltage V_{S} and current I are taken at each of a number of time windows 100, 200, 300 simultaneously in each waveform V_{S}, I. The results from each waveform V_{S}, I may be averaged over a plurality of the time windows 100, 200, 300 to obtain an average, reducing noise effects and providing more precise results. Clearly any appropriate number of time windows may be used and the windows may be of any appropriate length.

Being able to determine the location of an electrical disturbance, for example within a particular distribution leg from a plurality of distribution legs connected to a single power source, enables just the leg affected by the electrical disturbance to be isolated. The remaining portions of the circuit, such as various other loads for other components and the power source may continue in operation. This provides better availability of the overall electrical network such that it is more reliable.

Determining the relative phase of current and voltage waveforms across the circuit inductance produced by a voltage or current perturbation provides a reliable indicator of the location of the electrical disturbance, even in electrically noisy environments.

If, in a particular distribution leg, a current waveform produced by an electrical disturbance is before a voltage waveform, then the location of the electrical disturbance can be identified as being in that particular distribution leg. That particular distribution leg may then be isolated, for example using a switch. If the current waveform produced by an electrical disturbance is not before the voltage waveform, then the location of the electrical disturbance can be identified as being elsewhere, for example on the power source side of the circuit or in another distribution leg.

The relative phase of the current and voltage waveforms across the circuit inductance may be determined by calculating the sign (positive or negative) of the inductance at a particular point in the circuit.

Many variations may be made to the examples described above whilst still falling within the scope of the present invention. For example, the relative phase of current and voltage waveforms across the circuit inductance produced by a voltage or current perturbation may be determined by any appropriate technique, such as by comparison of times at which the voltage and current peaks occur as an alternative to determining the sign (positive or negative) of the inductance within the distribution leg. Furthermore, the controller 30 may be provided by any appropriate technique such as a component provided within the circuit or within the switch mechanism 40 and/or may at least partly be provided by one or more components external to the circuit 10 which may or may not include a microprocessor or computer.

What is claimed is:

1. An apparatus for determining the location of an electrical disturbance in a circuit, the apparatus comprising:
at least one sensor configured to determine the relative phase of current and voltage waveforms across the circuit inductance of a portion of the circuit produced by a voltage or current perturbation; and
a controller configured to identify the location of the electrical disturbance within the circuit from the relative phase of the current and voltage waveforms.

2. The apparatus according to claim 1, wherein the controller is configured to isolate a portion of a circuit including the location at which the electrical disturbance occurred.

3. The apparatus according to claim 2, wherein the controller is configured to isolate the portion of the circuit in which the electrical disturbance occurred by opening a switch.

4. The apparatus according to claim 1, wherein the controller is configured to determine the relative phase of current and voltage waveforms across the circuit inductance produced by a voltage or current perturbation by determining the inductance of a portion of the circuit.

5. The apparatus according to claim 4, wherein the inductance in a portion of the circuit is determined based on the rate of change of current through the portion of the circuit, the voltage across the portion of the circuit and the voltage across the capacitive component of a load within the portion of the circuit.

6. The apparatus according to claim 5, wherein the voltage across the capacitive component of a load within the portion of the circuit is measured by low-pass filtering the voltage across the portion of the circuit.

7. A circuit comprising:
a power source;
at least one distribution leg comprising a load; and
at least one apparatus for determining the location of an electrical disturbance in a circuit, the apparatus comprising:
at least one sensor configured to determine the relative phase of current and voltage waveforms across the circuit inductance of a portion of the circuit produced by a voltage or current perturbation; and
a controller configured to identify the location of the electrical disturbance within the circuit from the relative phase of the current and voltage waveforms,
wherein the apparatus is configured to identify the location of an electrical disturbance within the power source portion or the at least one distribution leg.

8. The circuit according to claim 7, comprising a plurality of distribution legs, wherein of the each of the plurality of distribution legs comprises an apparatus for determining the location of an electrical disturbance in a circuit, and wherein each apparatus is configured to identify the occurrence of an electrical disturbance in one of the plurality of distribution legs.

9. A method for determining the location of an electrical disturbance in a circuit, the method comprising:
determining the relative phase of current and voltage waveforms across the circuit inductance of a portion of the circuit produced by a voltage or current perturbation in the circuit; and
identifying the location of the electrical disturbance within the circuit from the determined relative phase of the current and voltage waveforms in that portion of the circuit.

10. The method according to claim 9, wherein determining the relative phase of current and voltage waveforms across the circuit inductance of a portion of the circuit produced by a voltage or current perturbation in the circuit comprises calculating the sign of the inductance of the circuit during the voltage or current perturbation.

11. The method according to claim 9, wherein the relative phase of the current and voltage waveforms produced by a voltage or current perturbation are determined for each of a plurality of distribution legs each supplying a different load in the circuit, such that the distribution leg in which the voltage or current perturbation occurred may be identified.

12. The method according to claim 9, further comprising isolating the portion of the circuit identified as including the location of an electrical disturbance from the remainder of the circuit.
